(19) United States
(12) Patent Application Publication
(10) Pub. No.: US 2024/0014051 A1
(43) Pub. Date: Jan. 11, 2024

(54) WAFER TEMPERATURE CONTROL DEVICE

(71) Applicant: KELK Ltd., Hiratsuka-shi (JP)

(72) Inventors: Atsushi Kobayashi, Hiratsuka-shi (JP); Wataru Omuro, Hiratsuka-shi (JP)

(73) Assignee: KELK Ltd., Hiratsuka-shi (JP)

(21) Appl. No.: 18/021,852

(22) PCT Filed: Sep. 1, 2021
(86) PCT No.: PCT/JP2021/032132

§ 371 Date: Feb. 17, 2023

(30) Foreign Application Priority Data
Sep. 14, 2020 (JP) 2020-153856

(51) Int. Cl. H01L 21/67

(52) U.S. Cl. CPC H01L 21/67103; H01L 21/67017

(57) ABSTRACT

A wafer temperature control device includes a temperature control sheet; and a top plate. The temperature control sheet includes a plurality of temperature control portions. The plurality of temperature control portions are divided from each other via a division region in the same plane. The plurality of temperature control portions are each independently controllable in temperature. The top plate includes a plate body stacked on the temperature control sheet. A surface of the plate body serves as a placement surface for a semiconductor wafer, the surface being opposite the temperature control sheet. The top plate includes a heat insulating portion. The heat insulating portion is disposed at a position corresponding to the division region in the plate body, when viewed in a stacking direction of the temperature control sheet and the top plate. The heat insulating portion has a thermal conductivity lower than a thermal conductivity of the plate body.

### TECHNICAL FIELD

The present invention relates to a wafer temperature control device.

Priority is claimed on Japanese Patent Application No. 2020-153856, filed on Sep. 14, 2020, the content of which is incorporated herein by reference.

### BACKGROUND ART

Patent Document 1 discloses a circular cooling plate that cools a wafer. The circular cooling plate includes a thermo-module in which a plurality of Peltier elements are disposed between a pair of heat transfer plates. Furthermore, in Patent Document 1, by devising the shape of the pair of heat transfer plates or a disposition of the plurality of Peltier elements in various ways, it is possible dispose the thermo-module as close to the wafer as possible, to improve cooling capacity and to reduce temperature variation.

### CITATION LIST

### Patent Document

### Patent Document 1

Japanese Unexamined Patent Application, First Publication No. 2002-185051

### SUMMARY OF INVENTION

### Technical Problem

In a wafer temperature control device that controls temperature of a wafer as disclosed in Patent Document 1, in order to suppress an influence on a back surface of the wafer, it is desirable that the back surface of the wafer is supported from below by a smooth surface without irregularities.

Further, in the wafer temperature control device described above, instead of reducing temperature variation in the wafer, it is desirable that a plurality of zones be set within a wafer surface and temperature is independently controlled for each zone. However, even when an attempt is made to differentiate the temperature of the zones adjacent to each other, a desired temperature may not be obtainable in the vicinity of the boundary of the adjacent zones due to heat conduction in the smooth surface supporting the wafer.

The present invention is conceived in view of such a problem, and an object of the present invention is to provide a wafer temperature control device capable of favorably controlling temperature for each of a plurality of zones.

### Solution to Problem

A wafer temperature control device according to one aspect of the present invention includes: a temperature control sheet; and a top plate. The temperature control sheet is configured to include a plurality of temperature control portions. The plurality of temperature control portions are divided from each other via a division region in the same plane. The plurality of temperature control portions are each independently controllable in temperature. The top plate is configured to include a plate body stacked on the temperature control sheet. A surface of the plate body serves as a placement surface for a semiconductor wafer, the surface being opposite the temperature control sheet. The top plate includes a heat insulating portion. The heat insulating portion is disposed at a position corresponding to the division region in the plate body, when viewed in a stacking direction of the temperature control sheet and the top plate. The heat insulating portion has a thermal conductivity lower than the thermal conductivity of the plate body.

### Advantageous Effects of Invention

According to the present invention, it is possible to favorably control the temperature for each of a plurality of the division regions.

### BRIEF DESCRIPTION OF DRAWINGS

FIG. 1 is an elevational cross-sectional view showing a schematic configuration of a wafer temperature control device according to an embodiment of the present invention.

FIG. 2 is a cross-sectional view taken along line I-I of FIG. 1.

FIG. 3 is a cross-sectional view taken along line II-II of FIG. 1.

FIG. 4 is a plan view of a top plate of the temperature control device.

FIG. 5 is an elevational cross-sectional view showing a schematic configuration of a wafer temperature control device according to a modification example of the embodiment of the present invention.

### DESCRIPTION OF EMBODIMENTS

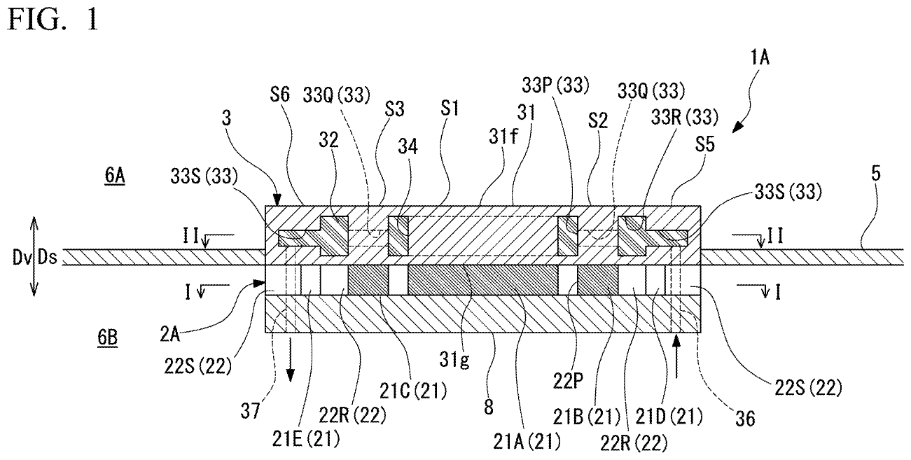

Hereinafter, an embodiment of the present invention will be described in detail below with reference to FIGS. 1 to 4.

<Wafer Temperature Control Device>

A wafer temperature control device (hereinafter, simply referred to as a temperature control device) according to the present embodiment is installed in, for example, a semiconductor manufacturing apparatus. The temperature control device supports a semiconductor wafer from below, which is subjected to predetermined processing such as plasma processing or etching processing in the semiconductor manufacturing apparatus. The temperature control device controls the temperature of the semiconductor wafer to a temperature suitable for predetermined processing.

FIG. 1 is an elevational cross-sectional view showing a schematic configuration of a wafer temperature control device according to an embodiment of the present invention.

As shown in FIG. 1, a temperature control device 1A according to the present embodiment is supported by a chamber 5 of a semiconductor manufacturing apparatus. The temperature control device 1A partitions an upper space 6A that is the inside of the chamber 5 and a lower space 6B that is the outside of the chamber 5. The upper space 6A is disposed above the temperature control device 1A in an up-down direction Dv. The lower space 6B is disposed below the temperature control device 1A in the up-down direction Dv. In the present embodiment, for example, the upper space 6A is vacuum-drawn to a degree of vacuum suitable for predetermined processing.

The temperature control device 1A includes a temperature control sheet 2A, a top plate 3, and a cooling plate 8. The temperature control sheet 2A, the top plate 3, and the cooling plate 8 are stacked and disposed in the up-down direction Dv.

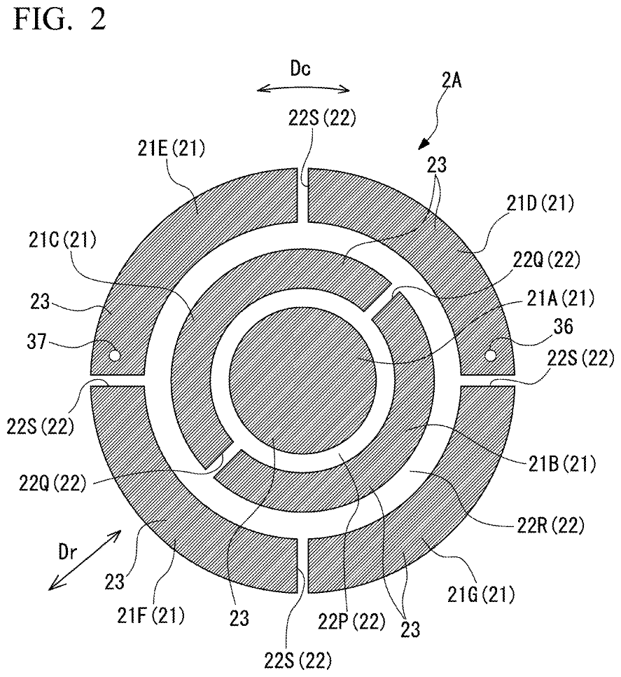

FIG. 2 is a cross-sectional view taken along line I-I of FIG. 1.

As shown in FIG. 2, in the present embodiment, a contour of the temperature control sheet 2A when viewed in the up-down direction Dv (direction perpendicular to the drawing sheet of FIG. 2) has, for example, a circular shape. The temperature control sheet 2A includes a plurality of temperature control portions 21. The plurality of temperature control portions 21 in the present embodiment are separated from each other in the same plane (horizontal plane) orthogonal to a stacking direction Ds of the temperature control sheet 2A and the top plate 3 (the up-down direction Dv), to interpose division regions 22 therebetween. In the present embodiment, the plurality of temperature control portions 21 include, for example, an inner peripheral temperature control portion 21A, intermediate temperature control portions 21B and 21C, and outer peripheral temperature control portions 21D to 21G.

The inner peripheral temperature control portion 21A is disposed at a circular central portion of the temperature control sheet 2A when viewed in the up-down direction Dv. The inner peripheral temperature control portion 21A shown as an example in the present embodiment has a circular shape when viewed in the up-down direction Dv.

The intermediate temperature control portions 21B and 21C are disposed outside the inner peripheral temperature control portion 21A in a radial direction Dr of the temperature control sheet 2A, and are disposed to surround the temperature control sheet 2A. Specifically, each of the intermediate temperature control portions 21B and 21C in the present embodiment is formed in a semicircular arc shape. Then, the intermediate temperature control portions 21B and 21C each having a semicircular arc shape are arranged in a circumferential direction Dc to form a substantially annular shape.

The inner peripheral temperature control portion 21A and the intermediate temperature control portions 21B and 21C are separated from each other in the radial direction Dr via a first division region 22P having an annular shape that is continuous in the circumferential direction Dc of the temperature control sheet 2A. In addition, the intermediate temperature control portion 21B and the intermediate temperature control portion 21C are disposed at intervals from each other in the circumferential direction Dc with second division regions 22Q interposed therebetween. Each of the second division regions 22Q extends in the radial direction Dr to connect the first division region 22P and a third division region 22R to be described later.

The outer peripheral temperature control portions 21D to 21G are disposed outside the intermediate temperature control portions 21B and 21C in the radial direction Dr of the intermediate temperature control portions 21B and 21C and are disposed to surround the intermediate temperature control portions 21B and 21C. Specifically, each of the outer peripheral temperature control portions 21D to 21G in the present embodiment is formed in an arc shape. Then, the outer peripheral temperature control portions 21D to 21G each having an arc shape are arranged in the circumferential direction Dc to form a substantially annular shape. The outer peripheral temperature control portions 21D to 21G are disposed at an outermost peripheral portion of the temperature control sheet 2A.

The intermediate temperature control portions 21B and 21C and the outer peripheral temperature control portions 21D to 21G are separated from each other in the radial direction Dr via the third division region 22R having an annular shape that is continuous in the circumferential direction Dc. In addition, the outer peripheral temperature control portions 21D to 21G adjacent to each other in the circumferential direction Dc are separated from each other via four fourth division regions 22S disposed at intervals from each other in the circumferential direction Dc. Each of the fourth division regions 22S extends outward from the third division region 22R in the radial direction Dr.

Each of the plurality of temperature control portions 21 (the inner peripheral temperature control portion 21A, the intermediate temperature control portions 21B and 21C, and the outer peripheral temperature control portions 21D to 21G) is formed of, for example, a Peltier element or a sheet piece 23 with a built-in Peltier element. The temperature control sheet 2A includes a plurality of the sheet pieces 23 each having a predetermined shape. The plurality of sheet pieces 23 are disposed at intervals from each other such that the temperature control sheet 2A forms the first division region 22P, the second division regions 22Q, the third division region 22R, and the fourth division regions 22S.

Each of the plurality of temperature control portions 21 (sheet pieces 23) is controllable in temperature by an external controller (not shown). For example, the controller (not shown) controls energization of the Peltier element of each of the temperature control portions 21 (sheet pieces 23) to cause the plurality of temperature control portions 21 to be each independently controllable in temperature (temperature control).

As shown in FIG. 1, the cooling plate 8 is stacked on a lower side of the temperature control sheet 2A in the up-down direction Dv. The cooling plate 8 in the present embodiment is disposed on a side opposite the top plate 3 in the stacking direction Ds. The cooling plate 8 is made of, for example, metal such as copper or aluminum, resin, or ceramic. The cooling plate 8 is disposed in close contact with a lower surface of the temperature control sheet 2A. The cooling plate 8 absorbs heat emitted downward from the temperature control sheet 2A in the up-down direction Dv.

The top plate 3 is stacked on an upper side of the temperature control sheet 2A in the up-down direction Dv. The top plate 3 in the present embodiment is disposed on a side opposite the cooling plate 8 in the stacking direction Ds. In other words, a lower surface of the top plate 3 is in contact with an upper surface of the temperature control sheet 2A. The top plate 3 includes a plate body 31 and a heat insulating portion 32.

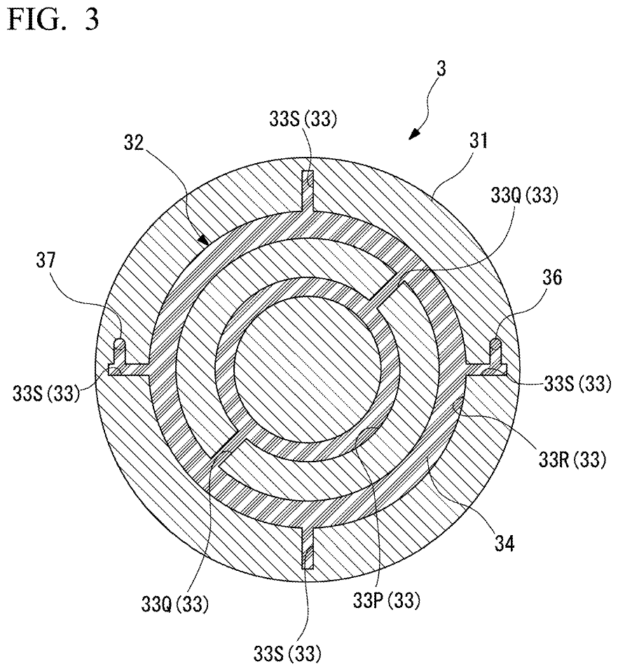

FIG. 3 is a cross-sectional view taken along line II-II of FIG. 1.

As shown in FIG. 3, in the present embodiment, a contour of the plate body 31 when viewed in the up-down direction Dv (direction orthogonal to the drawing sheet of FIG. 3) has, for example, a circular shape. The plate body 31 is formed to cover the entirety of the temperature control sheet 2A from above (refer to FIG. 2). The plate body 31 is made of, for example, a material such as an aluminum alloy or ceramic. A surface of the plate body 31 serves as a placement surface 31f for a semiconductor wafer, the surface being opposite the temperature control sheet 2A. The placement surface 31f is a smooth surface which intersects (is orthogonal to) the stacking direction Ds and in which a groove, a recessed portion, or the like is not formed.

As shown in FIGS. 1 and 3, the heat insulating portion 32 is formed inside the plate body 31. The heat insulating portion 32 is disposed at a position corresponding to the division regions 22 (in other words, a position where the heat insulating portion 32 overlaps the division regions 22 in the up-down direction Dv), when viewed in the stacking direction Ds (the up-down direction Dv) of the temperature control sheet 2A and the top plate 3. The heat insulating portion 32 in the present embodiment includes a space 33, a heat insulator 34, a fluid supply portion 36, and a fluid discharge portion 37.

The space 33 is formed inside the plate body 31. Namely, the space 33 is not exposed (open) to the placement surface 31f of the plate body 31 and to a facing surface 31g facing the temperature control sheet 2A on a side opposite the placement surface 31f. The space 33 is formed at a predetermined interval from each of the placement surface 31f and the facing surface 31g of the plate body 31 in the stacking direction Ds. The space 33 is continuously formed inside the plate body 31 in a direction along a horizontal plane orthogonal to the stacking direction Ds. The space 33 in the present embodiment is formed inside the plate body 31 at a position where the space 33 overlaps the division regions 22 when viewed in the stacking direction Ds (the up-down direction Dv). The space 33 includes a first space 33P, second spaces 33Q, a third space 33R, and fourth spaces 33S.

The first space 33P has an annular shape when viewed in the stacking direction Ds, and is formed at a position where the first space 33P overlaps the first division region 22P.

The second spaces 33Q extend in the radial direction Dr. The second spaces 33Q are disposed at intervals in the circumferential direction Dc at two locations. The second spaces 33Q in the present embodiment are disposed on an extension line extending in the radial direction Dr. The second spaces 33Q are formed at positions where the second spaces 33Q overlap the second division regions 22Q when viewed in the stacking direction Ds. The second spaces 33Q allow the first space 33P and the third space 33R to be described later to communicate with each other.

The third space 33R has an annular shape when viewed in the stacking direction Ds and is formed at a position where the third space 33R overlaps the third division region 22R.

The fourth spaces 33S extend outward from the third space 33R in the radial direction Dr. The fourth spaces 33S are disposed at intervals in the circumferential direction Dc at four locations. The fourth spaces 33S are formed at positions where the fourth spaces 33S overlap the fourth division regions 22S when viewed in the stacking direction Ds.

The heat insulator 34 is disposed in the space 33. In the present embodiment, for example, a liquid or gaseous fluid can be used as the heat insulator 34. The heat insulator 34 formed of a fluid is supplied from the outside of the temperature control device 1A, flows such that the space 33 is filled with the heat insulator 34, and is then discharged to the outside of the temperature control device 1A. As the heat insulator 34, a material having a thermal conductivity lower than that of the plate body 31, such as liquid such as air, nitrogen gas, an inert gas, water, and a fluorine-based refrigerant, can be used.

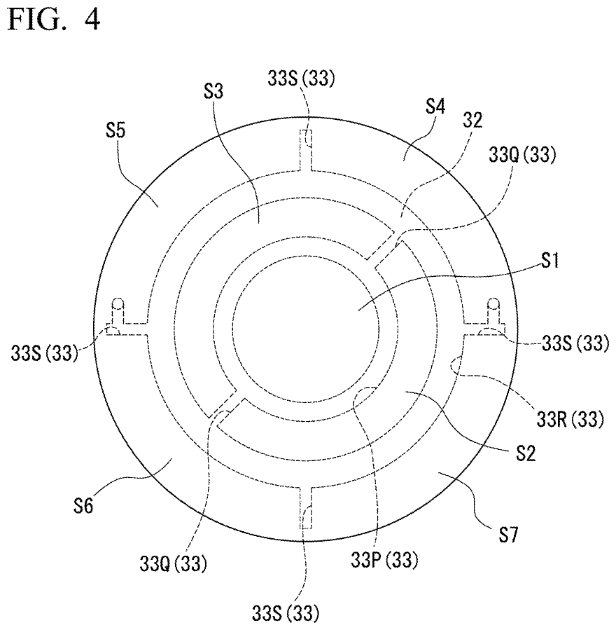

FIG. 4 is a plan view of the top plate of the temperature control device.

The top plate 3 is divided into a plurality of zones S shown in FIGS. 1 and 4 by the heat insulating portion 32 when viewed in the stacking direction Ds (direction orthogonal to the drawing sheet of FIG. 4). When viewed in the stacking direction Ds, the plurality of zones S correspond to (in other words, overlap in the up-down direction Dv) the plurality of temperature control portions 21 (the inner peripheral temperature control portion 21A, the intermediate temperature control portions 21B and 21C, and the outer peripheral temperature control portions 21D to 21G) shown in FIG. 2. As the plurality of zones S, an inner peripheral zone S1 corresponding to the inner peripheral temperature control portion 21A, intermediate zones S2 and S3 corresponding to the intermediate temperature control portions 21B and 21C, and outer peripheral zones S4 to S7 corresponding to the outer peripheral temperature control portions 21D to 21G are provided.

The fluid supply portion 36 supplies the fluid that is the heat insulator 34, into the space 33 from the outside of the temperature control device 1A. The fluid discharge portion 37 discharges the fluid that is the heat insulator 34, from the space 33 to the outside of the temperature control device 1A. One end of the fluid supply portion 36 and one end of the fluid discharge portion 37 each communicate with the space 33. The other end of the fluid supply portion 36 and the other end of the fluid discharge portion 37 are each open toward the outside of the temperature control device 1A.

The fluid supply portion 36 and the fluid discharge portion 37 in the present embodiment each extend downward from the space 33 formed in the plate body 31, in the stacking direction Ds (the up-down direction Dv). The fluid supply portion 36 and the fluid discharge portion 37 in the present embodiment are each disposed to communicate with the fourth spaces 33S. The fluid supply portion 36 and the fluid discharge portion 37 penetrate through the temperature control sheet 2A and through the cooling plate 8 in the stacking direction Ds, and are open to a lower surface of the cooling plate 8.

A feed pipe (not shown) through which the heat insulator 34 is fed from the outside by a pump (not shown) or the like is connected to the fluid supply portion 36. In addition, a discharge pipe (not shown) for discharging the heat insulator 34 to the outside is connected to the fluid discharge portion 37.

Incidentally, the heat insulator 34 to be fed into the space 33 from the fluid supply portion 36 may be configured to be controllable in temperature, pressure, flow rate, and the like as appropriate. In that case, a heat exchanger, a pump, or the like that controls temperature of the heat insulator 34 may be provided outside.

<Actions and Effects>

The temperature control device 1A includes the plurality of temperature control portions 21 that are each independently controllable in temperature. For this reason, the temperature of a semiconductor wafer placed on the placement surface 31f of the plate body 31 of the top plate 3 is controllable to different desired temperatures for each of the plurality of zones S. In addition, the top plate 3 includes the heat insulating portion 32 disposed at a position corresponding to the division regions 22 of the temperature control sheet 2A. For this reason, in the top plate 3, heat transferred from one temperature control portion 21 of the temperature control sheet 2A to one zone S is prevented from moving to another zone S to which heat from another temperature control portion 21 is transferred. Therefore, the temperature is favorably controllable for each of the plurality of zones S.

In addition, in the temperature control device 1A, the heat insulating portion 32 includes the space 33. Accordingly, inside the top plate 3, heat conduction between the adjacent zones S among the plurality of zones S corresponding to the plurality of temperature control portions 21 in the stacking direction Ds can be suppressed.

In addition, in the temperature control device 1A, the heat insulator 34 having a thermal conductivity lower than that of the plate body 31 exists in the space 33. Accordingly, heat conduction between the adjacent zones S of the top plate 3 can be much further suppressed.

In addition, in the temperature control device 1A, the fluid as the heat insulator 34 is fed into the space 33 from the outside through the fluid supply portion 36, and the fluid as the heat insulator 34 that has flowed through the space 33 is discharged from the fluid discharge portion 37. Accordingly, a change in the temperature of the heat insulator 34 caused by heat of the plurality of temperature control portions 21 can be suppressed. Therefore, heat transfer between the plurality of zones S of the top plate 3 can be more efficiently suppressed.

In addition, in the temperature control device 1A, the fluid supply portion 36 and the fluid discharge portion 37 extend in the stacking direction Ds and penetrate through the temperature control sheet 2A. For this reason, the fluid as the heat insulator 34 can flow into and out of the space 33 from the side opposite the placement surface 31f for the semiconductor wafer. In addition, heat exchanged between the zones S facing the space 33 can be moved in the stacking direction Ds by the fluid.

In addition, in the temperature control device 1A, the placement surface 31f is a smooth surface. For this reason, an influence on a back surface of the wafer can be reduced, and unlike a case where grooves or the like are formed in the placement surface 31f, foreign matter or the like does not enter grooves or the like, so that cleaning or maintenance of the placement surface 31f can be easily performed.

Further, in the temperature control device 1A, the temperature control sheet 2A includes the plurality of sheet pieces 23 forming the temperature control portions 21. For this reason, when the sheet pieces 23 adjacent to each other are disposed at intervals, the division regions 22 can also be easily formed.

### Modification Example of Embodiment

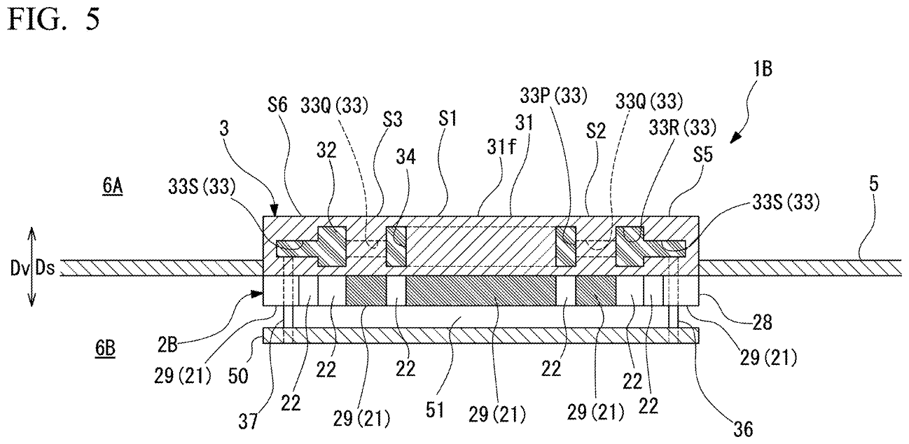

FIG. 5 is an elevational cross-sectional view showing a schematic configuration of a wafer temperature control device according to a modification example of the embodiment of the present invention.

In the embodiment, a Peltier element is used as the temperature control sheet 2A, but the present invention is not limited to this configuration.

For example, as shown in FIG. 5, an electric heater 28 may be used as a temperature control sheet 2B of a temperature control device 1B. The electric heater 28 includes a plurality of sheet pieces 29. Similarly to the temperature control sheet 2A of the embodiment shown in FIG. 2, the sheet pieces 29 form the plurality of temperature control portions 21 that are each independently controllable in temperature. The sheet pieces 29 are disposed at intervals from each other, so that the plurality of temperature control portions 21 are separated from each other via the division regions 22 in the same plane.

When the electric heater 28 is provided, a purge plate 50 may be disposed below from the electric heater 28 at an interval in the up-down direction Dv. Accordingly, a purge space 51 is formed between the electric heater 28 and the purge plate 50. When the temperature of the electric heater 28 is to be lowered, the temperature of the electric heater 28 can be efficiently lowered by purging air from the outside into the purge space 51.

In addition, when the purge plate 50 is provided, the fluid supply portion 36 and the fluid discharge portion 37 may be formed into a tubular shape, and may be provided to penetrate through the purge space 51 and through the purge plate 50 from the temperature control sheet 2B.

### Other Modification Examples

In the embodiment and the modification example, the plurality of temperature control portions 21 forming each of the temperature control sheets 2A and 2B are divided into the inner peripheral temperature control portion 21A, the intermediate temperature control portions 21B and 21C, and the outer peripheral temperature control portions 21D to 21G, but the present invention is not limited to this configuration. The number of and the division pattern of the plurality of temperature control portions 21 forming the temperature control sheet 2A can be changed as appropriate.

Further, the case in which in the temperature control sheet 2A, the first division region 22P, the second division regions 22Q, the third division region 22R, and the fourth division regions 22S are provided has been described, but the first division region 22P, the second division regions 22Q, the third division region 22R, and the fourth division regions 22S may be omitted, and the first division region 22P, the second division regions 22Q, the third division region 22R, and the fourth division regions 22S adjacent to each other in the circumferential direction Dc and in the radial direction Dr may be brought close to each other.

In addition, the space 33 is not exposed (open) to the placement surface 31f of the plate body 31 and to the facing surface 31g, but the present invention is not limited to this configuration. For example, the space 33 may be open to the facing surface 31g to communicate with the division regions 22 of the temperature control sheet 2A. In this case, the supply of the heat insulator 34 to or the filling of not only the space 33 but also the division regions 22 with the heat insulator 34 may be performed.

Further, in the embodiment, the case where only one space 33 is provided has been provided as an example, but the present invention is not limited to this case. For example, the space 33 may be divided into a plurality of segments.

In addition, in the embodiment, the case where one fluid supply portion 36 and one fluid discharge portion 37 are provided for one space 33 has been provided as an example, but the present invention is not limited to this case. For example, a plurality of the fluid supply portions 36 and a plurality of the fluid discharge portions 37 may be provided for one space 33.

In addition, the case where the plate body 31 is provided with a single space 33 has been described, but the plate body 31 may be provided with a plurality of the spaces 33 that do not communicate with each other, and the heat insulator 34 may be supplied to and discharged from the each of the spaces 33.

In addition, as the heat insulating portion 32, the heat insulator 34 formed of a fluid is supplied from the outside of the temperature control device 1A, but the present invention is not limited to this configuration. For example, the space 33 may simply be filled (in other words, enclosed) with the heat insulator 34 formed of a fluid. In addition, as the heat insulating portion 32, the space 33 may be filled with, for example, a solid-state heat insulating material such as carbon fibers having a heat insulating property. In addition, a gas having a pressure lower than the atmospheric pressure which is obtained by vacuum-drawing the space 33 using a vacuum pump or the like may be used as the heat insulating portion 32. In addition, for example, the space 33 may communicate with the upper space 6A. Accordingly, the heat insulating portion 32 can be configured by setting the space 33 to the same vacuum state as the upper space 6A.

### INDUSTRIAL APPLICABILITY

According to the present invention, it is possible to favorably control temperature for each of a plurality of the division regions.

### REFERENCE SIGNS LIST

1A, 1B: Wafer temperature control device
2A, 2B: Temperature control sheet
3: Top plate
5: Chamber
6A: Upper space
6B: Lower space
8: Cooling plate
21: Temperature control portion
21A: Inner peripheral temperature control portion
21B, 21C: Intermediate temperature control portion
21D, 21E, 21F, 21G: Outer peripheral temperature control portion
22: Division region
22P: First division region
22Q: Second division region
22R: Third division region
22S: Fourth division region
23: Sheet piece
28: Electric heater
29: Sheet piece
31: Plate body
31f: Placement surface
31g: Facing surface
32: Heat insulating portion
33: Space
33P: First space
33Q: Second space
33R: Third space
33S: Fourth space
34: Heat insulator
36: Fluid supply portion
37: Fluid discharge portion
50: Purge plate
51: Purge space
Dc: circumferential direction
Dr: radial direction
Ds: stacking direction
Dv: up-down direction
S: Zone
S1: Inner peripheral zone
S2, S3: Intermediate zone
S4, S5, S6, S7: Outer peripheral zone

1. A wafer temperature control device comprising:
a temperature control sheet configured to include a plurality of temperature control portions that are divided from each other via a division region in the same plane, and that are each independently controllable in temperature; and
a top plate configured to include a plate body which is stacked on the temperature control sheet, and of which a surface serves as a placement surface for a semiconductor wafer, the surface being opposite the temperature control sheet,
wherein the top plate includes a heat insulating portion disposed at a position corresponding to the division region in the plate body, when viewed in a stacking direction of the temperature control sheet and the top plate and having a thermal conductivity lower than a thermal conductivity of the plate body.

2. The wafer temperature control device according to claim 1,
wherein the heat insulating portion includes a space formed inside the plate body.

3. The wafer temperature control device according to claim 2,
wherein the heat insulating portion further includes a heat insulator which is supplied into the space or with which the space is filled, and which has a thermal conductivity lower than the thermal conductivity of the plate body.

4. The wafer temperature control device according to claim 3,
wherein the heat insulator is a fluid, and
the wafer temperature control device further comprises:
a fluid supply portion configured to supply the fluid into the space from an outside, and
a fluid discharge portion configured to discharge the fluid from the space to the outside.

5. The wafer temperature control device according to claim 4,
wherein the fluid supply portion and the fluid discharge portion are disposed to extend from the plate body in the stacking direction and to penetrate through the temperature control sheet.

6. The wafer temperature control device according to claim 1,
wherein the placement surface is a smooth surface intersecting the stacking direction.

7. The wafer temperature control device according to claim 2,
wherein the temperature control sheet includes a plurality of sheet pieces forming each of the temperature control portions.

8. The wafer temperature control device according to claim 2,
wherein the placement surface is a smooth surface intersecting the stacking direction.

9. The wafer temperature control device according to claim 3,
wherein the placement surface is a smooth surface intersecting the stacking direction.

10. The wafer temperature control device according to claim 4,
wherein the placement surface is a smooth surface intersecting the stacking direction.

11. The wafer temperature control device according to claim 5,
wherein the placement surface is a smooth surface intersecting the stacking direction.

12. The wafer temperature control device according to claim 3,
wherein the temperature control sheet includes a plurality of sheet pieces forming each of the temperature control portions.

13. The wafer temperature control device according to claim 4,
wherein the temperature control sheet includes a plurality of sheet pieces forming each of the temperature control portions.

14. The wafer temperature control device according to claim 5,
wherein the temperature control sheet includes a plurality of sheet pieces forming each of the temperature control portions.

15. The wafer temperature control device according to claim 6,
wherein the temperature control sheet includes a plurality of sheet pieces forming each of the temperature control portions.

16. The wafer temperature control device according to claim 8,
wherein the temperature control sheet includes a plurality of sheet pieces forming each of the temperature control portions.

17. The wafer temperature control device according to claim 9,
wherein the temperature control sheet includes a plurality of sheet pieces forming each of the temperature control portions.

18. The wafer temperature control device according to claim 10,
wherein the temperature control sheet includes a plurality of sheet pieces forming each of the temperature control portions.

19. The wafer temperature control device according to claim 11,
wherein the temperature control sheet includes a plurality of sheet pieces forming each of the temperature control portions.
